(19) United States
(12) Patent Application Publication
(10) Pub. No.: US 2025/0104975 A1
(43) Pub. Date: Mar. 27, 2025

(54) PLASMA PROCESSING APPARATUS

(71) Applicant: Tokyo Electron Limited, Tokyo (JP)

(72) Inventors: Taro IKEDA, Nirasaki City (JP); Toshifumi KITAHARA, Fuchu City (JP)

(21) Appl. No.: 18/975,131

(22) Filed: Dec. 10, 2024

Related U.S. Application Data
(63) Continuation of application No. PCT/JP2023/021400, filed on Jun. 8, 2023.

(30) Foreign Application Priority Data
Jun. 16, 2022 (JP) 2022-097169

(51) Int. Cl. H01J 37/32; C23C 16/455; C23C 16/50

(52) U.S. Cl. CPC H01J 37/32229; C23C 16/45565; C23C 16/50; H01J 37/32357; H01J 37/3244

(57) ABSTRACT

A plasma processing apparatus includes a chamber and a waveguide portion. The waveguide portion is configured to propagate electromagnetic waves to generate plasma within the chamber. The waveguide portion includes a resonator configured to resonate the electromagnetic waves therein. The resonator includes a microstrip and a dielectric member. A part of the dielectric member constitutes a dielectric layer of the microstrip.

### CROSS-REFERENCE TO RELATED APPLICATIONS

This application is a bypass continuation application of International Application No. PCT/JP2023/021400 having an international filing date of Jun. 8, 2023 and designating the United States, the international application being based upon and claiming the benefit of priority from Japanese Patent Application No. 2022-097169, filed on Jun. 16, 2022, the entire contents of which are incorporated herein by reference.

### TECHNICAL FIELD

Exemplary embodiments of the present disclosure relate to a plasma processing apparatus.

### BACKGROUND

A plasma processing apparatus has been used in manufacturing a device. Patent Document 1 below discloses a plasma processing apparatus using very high frequency (VHF) waves. The VHF waves are introduced into a chamber via a power feeder. The power feeder includes a resonator. The resonator includes a pair of metal reflective plates. The pair of metal reflectors is arranged at an interval of ¼ of the wavelength of the VHF waves.

### PRIOR ART DOCUMENTS

### Patent Documents

Patent Document 1: Japanese patent laid-open publication No. 2019-106290

### SUMMARY

According to one embodiment of the present disclosure, a plasma processing apparatus is provided. The plasma processing apparatus includes a chamber and a waveguide portion. The waveguide portion is configured to propagate electromagnetic waves to generate plasma within the chamber. The waveguide portion includes a resonator configured to resonate the electromagnetic waves therein. The resonator includes a microstrip and a dielectric member. A part of the dielectric member constitutes a dielectric layer of the microstrip.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a cross-sectional view schematically showing a plasma processing apparatus according to one exemplary embodiment.

FIG. 2 is a partially enlarged cross-sectional view of a waveguide portion of the plasma processing apparatus according to one exemplary embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, various exemplary embodiments of the present disclosure will be described in detail with reference to the accompanying drawings. In each drawing, the same or corresponding parts will be denoted by the same reference numerals.

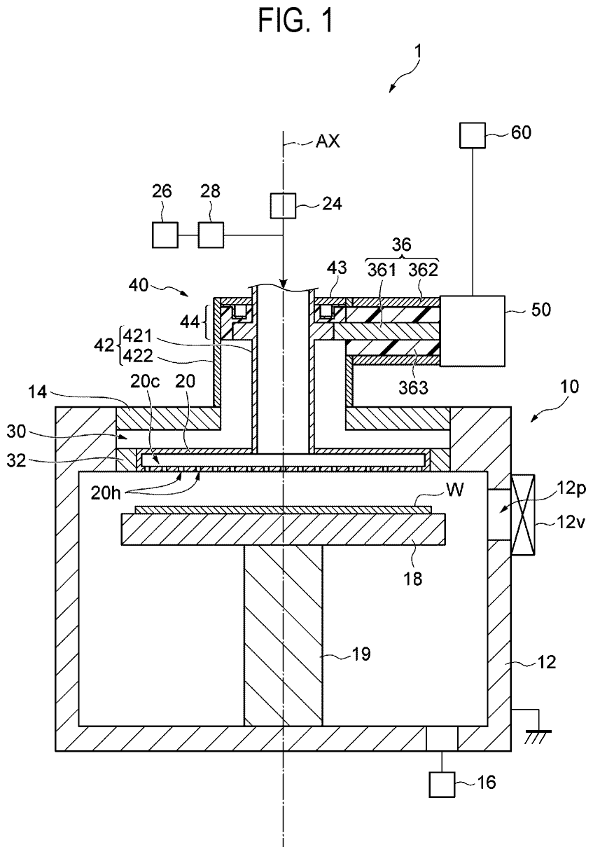

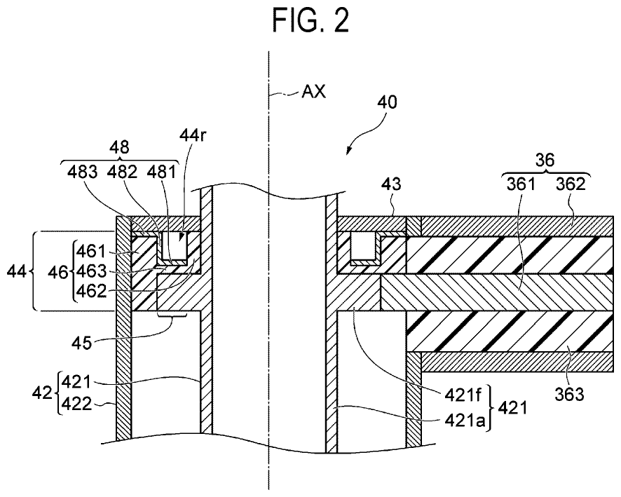

FIG. 1 is a cross-sectional view schematically showing a plasma processing apparatus according to one exemplary embodiment. FIG. 2 is a partially enlarged cross-sectional view of a waveguide portion of the plasma processing apparatus according to one exemplary embodiment. A plasma processing apparatus 1 shown in FIGS. 1 and 2 is configured to generate plasma by electromagnetic waves. The electromagnetic waves are VHF waves or ultra-high frequency (UHF) waves. A band of the VHF waves is 30 MHz to 300 MHZ, and a band of the UHF waves is 300 MHz to 3 GHz.

The plasma processing apparatus 1 includes a chamber 10. The chamber 10 defines an internal space. A substrate W is processed in the internal space of the chamber 10. The chamber 10 has an axis line AX as a central axis line thereof. The axis line AX extends in a vertical direction.

In one embodiment, the chamber 10 may include a chamber body 12. The chamber body 12 has a substantially cylindrical shape and is open at an upper portion thereof. The chamber body 12 provides a side wall and a bottom portion of the chamber 10. The chamber body 12 is formed of a metal such as aluminum. The chamber body 12 is grounded.

The side wall of the chamber body 12 provides a passage 12p. The substrate W passes through the passage 12p when the substrate W is transferred between the inside and outside of the chamber 10. The passage 12p can be opened and closed by a gate valve 12v. The gate valve 12v is provided along the side wall of the chamber body 12.

The chamber 10 may further include an upper wall 14. The upper wall 14 is formed of a metal such as aluminum. The upper wall 14 closes an opening of the upper portion of the chamber body 12 together with a coaxial waveguide tube 42, which will be described later. The upper wall 14 in addition to the chamber body 12 is grounded.

The bottom portion of the chamber 10 provides an exhaust port. The exhaust port is connected to an exhaust device 16. The exhaust device 16 includes a pressure regulator, such as an automatic pressure control valve, and a vacuum pump, such as a turbo molecular pump.

The plasma processing apparatus 1 may further include a substrate support 18. The substrate support 18 is provided within the chamber 10. The substrate support 18 is configured to support the substrate W placed thereon. The substrate W is placed on the substrate support 18 in a substantially horizontal state. The substrate support 18 may be supported by a support member 19. The support member 19 extends upward from the bottom portion of the chamber 10. The substrate support 18 and the support member 19 may be formed of a dielectric material such as aluminum nitride.

The plasma processing apparatus 1 may further include a shower head 20. The shower head 20 is formed of a metal such as aluminum. The shower head 20 has a substantially disc shape and may have a hollow structure. The shower head 20 shares the axis line AX as a central axis line thereof. The shower head 20 is provided above the substrate support 18 and below the upper wall 14. The shower head 20 constitutes a ceiling portion that defines the internal space of the chamber 10.

The shower head 20 provides a plurality of gas holes 20h. The plurality of gas holes 20h is open toward the internal space of the chamber 10. The shower head 20 also provides a gas diffusion chamber 20c therein. The plurality of gas holes 20h is connected to the gas diffusion chamber 20c and extends downward from the gas diffusion chamber 20c.

The plasma processing apparatus 1 may include an inner conductor 421 of the coaxial waveguide tube 42, which will be described later, as a gas supply tube. The inner conductor 421 is configured as a tube having a cylindrical shape. The inner conductor 421 is formed of a metal such as aluminum. The inner conductor 421 extends vertically above the shower head 20. The inner conductor 421 shares the axis line AX as a central axis line thereof. A lower end of the inner conductor 421 is connected to an upper center of the shower head 20. The upper center of the shower head 20 provides an inlet of gas. The inlet is connected to the gas diffusion chamber 20c. The inner conductor 421 supplies gas to the shower head 20. The gas from the inner conductor 421 is introduced into the chamber 10 from the plurality of gas holes 20h via the inlet of the shower head 20 and the gas diffusion chamber 20c.

In one embodiment, the plasma processing apparatus 1 may further include a first gas source 24, a second gas source 26, and a remote plasma source 28. The first gas source 24 is connected to the inner conductor 421 (i.e., gas supply tube). The first gas source 24 may be a gas source of a film forming gas. The film forming gas may include a silicon-containing gas. The silicon-containing gas includes, for example, SiH₄. The film forming gas may further include other gases. For example, the film forming gas may further include NH₃ gas, N₂ gas, a noble gas such as Ar, and the like. The gas (e.g., film forming gas) from the first gas source 24 is introduced into the chamber 10 from the shower head 20 via the inner conductor 421 (i.e., gas supply tube).

The second gas source 26 is connected to the inner conductor 421 (i.e., gas supply tube) via the remote plasma source 28. The second gas source 26 can be a gas source of a cleaning gas. The cleaning gas may include a halogen-containing gas. The halogen-containing gas may include, for example, NF₃ and/or Cl₂. The cleaning gas may further include other gases. The cleaning gas may further include a noble gas such as Ar.

The remote plasma source 28 generates plasma by exciting a gas from the second gas source 26 at a location separated from the chamber 10. In one embodiment, the remote plasma source 28 generates plasma from the cleaning gas. The remote plasma source 28 may be any type of plasma source. Examples of the remote plasma source 28 include a capacitively coupled plasma source, an inductively coupled plasma source, or a plasma source that generates plasma using microwaves. Radicals in the plasma generated in the remote plasma source 28 are introduced into the chamber 10 from the shower head 20 via the inner conductor 421.

In order to suppress the radicals from being deactivated, the inner conductor 421 (i.e., gas supply tube) may have a relatively large diameter. An outer diameter (diameter) of the inner conductor 421 is, for example, 40 mm or more. In one example, the outer diameter (diameter) of the inner conductor 421 is 80 mm. The inner conductor 421 has a cylindrical shape, and the outer diameter (diameter) of the inner conductor 421 is an outer diameter of the inner conductor 421 at a portion 421a of the inner conductor 421 other than a flange portion 421f to be described later. The flange portion 421f constitutes a part of the inner conductor 421 in a longitudinal direction. The flange portion 421f has an annular shape and extends centered on the axis line AX. The flange portion 421f protrudes in a radial direction from the portion 421a of the inner conductor 421. The inner conductor 421 may constitute a part of a waveguide portion 40 to be described later.

The shower head 20 is separated downward from the upper wall 14. A space between the shower head 20 and the upper wall 14 forms a part of a waveguide path 30. The waveguide path 30 also includes a space provided by the inner conductor 421 between the inner conductor 421 and the upper wall 14.

The plasma processing apparatus 1 may further include an introduction portion 32. The introduction portion 32 is formed of a dielectric material such as aluminum oxide. The introduction portion 32 is provided along an outer periphery of the shower head 20 so as to introduce electromagnetic waves into the chamber 10 therefrom. The introduction portion 32 has an annular shape. The introduction portion 32 closes a gap between the shower head 20 and the chamber body 12 and is connected to the waveguide path 30. The introduction portion 32 may be provided along the side wall of the chamber 10.

The plasma processing apparatus 1 further includes the waveguide portion 40. The waveguide portion 40 is configured to propagate electromagnetic waves in order to generate plasma in the chamber 10. The waveguide portion 40 may be provided above the chamber 10.

The plasma processing apparatus 1 may further include an electromagnetic wave supply path 36. The supply path 36 is connected to the waveguide portion 40. In one embodiment, the supply path 36 has a coaxial structure. That is, the supply path 36 includes a central conductor 361 and an outer conductor 362. The outer conductor 362 has a substantially cylindrical shape. The outer conductor 362 is connected to an outer conductor 422 of the coaxial waveguide tube 42. The central conductor 361 has a rod shape and is provided coaxially with the outer conductor 362 in the outer conductor 362. The supply path 36 may further include a dielectric member 363. The dielectric member 363 fills a gap between the central conductor 361 and the outer conductor 362. The dielectric member 363 is formed of, for example, polytetrafluoroethylene (PTFE).

The central conductor 361 is connected to the inner conductor 421. Specifically, one end of the central conductor 361 is connected to the flange portion 421f. The flange portion 421f may be a part of the central conductor 361. Alternatively, the flange portion 421f may be configured by the inner conductor 421 and the central conductor 361.

The plasma processing apparatus 1 may further include a matcher 50 and a power supply 60. The other end of the central conductor 361 is connected to the power supply 60 via the matcher 50. The power supply 60 is an electromagnetic wave generator. The matcher 50 has an impedance matching circuit. The impedance matching circuit is configured to match a load impedance of the power supply 60 to an output impedance of the power supply 60. The impedance matching circuit has a variable impedance. The impedance matching circuit may be, for example, a π-type circuit.

In the plasma processing apparatus 1, electromagnetic waves from the power supply 60 are introduced into the chamber 10 from the introduction portion 32 via the matcher 50, the supply path 36 (central conductor 361), the waveguide portion 40, and the waveguide path 30 around the shower head 20. The electromagnetic waves generate plasma by exciting the gas (e.g., film forming gas) from the first gas source 24 into the chamber 10.

The waveguide portion 40 includes a resonator 44. The waveguide portion 40 may further include the coaxial waveguide tube 42 and a lid 43 (lid conductor). In one embodiment, the coaxial waveguide tube 42 extends vertically above the chamber 10, and a central axis line thereof is the axis line AX. The coaxial waveguide tube 42 includes the inner conductor 421 and the outer conductor 422 described above. The outer conductor 422 is formed of a metal such as aluminum and has a substantially cylindrical shape. The inner conductor 421 is provided coaxially with the outer conductor 422 in the outer conductor 422.

The lid 43 is formed of a metal such as aluminum and closes an opening between the inner conductor 421 and the outer conductor 422 at one end (e.g., upper end) of the coaxial waveguide tube 42. The lid 43 is electrically connected to the outer conductor 422. The other end (e.g., lower end) of the outer conductor 422 is connected to the upper wall 14.

The resonator 44 is configured to resonate electromagnetic waves therein. The resonator 44 includes a microstrip 45 and a dielectric member 46. The resonator 44 may be provided between one end (e.g., upper end) and the other end (e.g., lower end) of the coaxial waveguide tube 42. That is, the microstrip 45 and the dielectric member 46 may be provided between one end (e.g., upper end) and the other end (e.g., lower end) of the coaxial waveguide tube 42. In one embodiment, the resonator 44 is provided from a lower surface of the flange portion 421f to a space above the flange portion 421f.

The dielectric member 46 is formed of, for example, polytetrafluoroethylene (PTFE). The dielectric member 46 includes a dielectric layer 463 as a part thereof. The dielectric layer 463 constitutes the microstrip 45. Thus, in the plasma processing apparatus 1, a part of the dielectric member 46 constitutes the dielectric layer 463 of the microstrip. Other parts of the dielectric member 46 also constitute the resonator 44. Therefore, the resonator 44 includes a plurality of parts having different impedances. In the plasma processing apparatus 1, the resonator 44 can resonate the electromagnetic waves, even though the size thereof is small, due to the microstrip 45 and the dielectric member 46.

In an embodiment, the resonator 44 may further include a ground conductor 48 in addition to the dielectric member 46. The ground conductor 48 may be provided on the dielectric member 46. The ground conductor 48 is electrically connected to the lid 43.

The microstrip 45 of the resonator 44 may include a microstrip conductor, the dielectric layer 463, and an annular ground portion 481. The microstrip conductor of the microstrip 45 is the flange portion 421f described above. The dielectric layer 463 has an annular shape and extends centered on the axis line AX. The dielectric layer 463 is provided on the microstrip conductor, i.e., the flange portion 421f. The annular ground portion 481 is a part of the ground conductor 48. The annular ground portion 481 has an annular shape and extends centered on the axis line AX. The annular ground portion 481 is provided on the dielectric layer 463.

In one embodiment, the dielectric member 46 may further include a first cylindrical portion 461 and a second cylindrical portion 462. The first cylindrical portion 461 has a substantially cylindrical shape. The first cylindrical portion 461 is interposed between an outer edge of the flange portion 421f and the outer conductor 422 and extends toward one end (e.g., upper end) of the coaxial waveguide tube 42. A central axis line of the first cylindrical portion 461 may be the axis line AX.

The second cylindrical portion 462 has a substantially cylindrical shape. The second cylindrical portion 462 is provided inside the first cylindrical portion 461 and extends from the flange portion 421f along the inner conductor 421 toward one end (e.g., upper end) of the coaxial waveguide tube 42. A central axis line of the second cylindrical portion 462 may be the axis line AX.

The dielectric layer 463 extends between the first cylindrical portion 461 and the second cylindrical portion 462. The dielectric layer 463 may extend between a middle position of the first cylindrical portion 461 in a longitudinal direction (height direction) and a lower end of the second cylindrical portion 462.

In one embodiment, the dielectric member 46 may provide a recess 44r. The recess 44r is a cavity and extends on the dielectric layer 463 and between the first cylindrical portion 461 and the second cylindrical portion 462. The recess 44r has an annular shape and extends centered on the axis line AX.

The above-described ground conductor 48 may further include a cylindrical ground portion 482. The cylindrical ground portion 482 has a substantially cylindrical shape and extends centered on the axis line AX. The cylindrical ground portion 482 extends from an outer edge of the annular ground portion 481 toward one end (e.g., upper end) of the coaxial waveguide tube 42 along the first cylindrical portion 461.

The ground conductor 48 may further include another annular ground portion 483. The annular ground portion 483 has an annular shape and extends centered on the axis line AX. The annular ground portion 483 extends outward in a radial direction from one end (e.g., upper end) of the cylindrical ground portion 482. The ground conductor 48 may be electrically connected to the lid 43 by clamping the annular ground portion 483 between the lid 43 and the first cylindrical portion 461 of the dielectric member 46.

In one embodiment, the dielectric member 46 can provide different impedances in the first cylindrical portion 461, the microstrip 45, the second cylindrical portion 462, and the recess 44r. Therefore, it is possible to resonate the electromagnetic waves in the resonator 44 due to the dielectric member 46 even if the size of the dielectric member 46 is considerably small.

In addition, the intensity of an electric field of the electromagnetic waves propagating from the microstrip 45 toward the recess 44r increases in an area along the inner conductor 421 but, since the second cylindrical portion 462 is installed in the area, abnormal discharge in the area is suppressed.

In the plasma processing apparatus 1, the inner conductor 421 is connected to the upper center of the shower head 20, and the central conductor 361 of the electromagnetic wave supply path 36 is connected to the flange portion 421f of this inner conductor 421. Therefore, the electromagnetic waves propagate uniformly around the inner conductor 421. The electromagnetic waves are introduced into the chamber 10 via the inner conductor 421 and the shower head 20 from the introduction portion 32 provided along the outer periphery of the shower head 20. Therefore, according to the plasma processing apparatus 1, the uniformity of plasma density distribution in the chamber 10 can be raised.

Furthermore, according to the plasma processing apparatus 1, a deposit formed in the chamber 10 by a film formation process can be removed by radicals from plasma of a cleaning gas. The radicals from the plasma of the cleaning gas are supplied via the inner conductor 421, which is the gas supply tube, and the shower head 20, so that the radicals are suppressed from being deactivated and the radicals are uniformly supplied into the chamber 10. Therefore, according to the plasma processing apparatus 1, the chamber 10 can be cleaned uniformly and efficiently.

According to one exemplary embodiment, a technique for reducing the size of an electromagnetic wave resonator in a plasma processing apparatus is provided.

While various exemplary embodiments have been described above, the present disclosure is not limited to the above-described exemplary embodiments, and various additions, omissions, substitutions, and modifications may be made. In addition, elements in different embodiments can be combined to form other embodiments.

Various exemplary embodiments included in the present disclosure are described in [E1] to [E12] below.

### [E1]

There is provided a plasma processing apparatus, including:
a chamber; and
a waveguide portion configured to propagate electromagnetic waves to generate plasma within the chamber, the waveguide portion including a resonator configured to resonate the electromagnetic waves therein,
wherein the resonator includes a microstrip and a dielectric member, and
wherein a part of the dielectric member constitutes a dielectric layer of the microstrip.

In the embodiment of [E1], the part of the dielectric member constitutes the dielectric layer of the microstrip. Other parts of the dielectric member also constitute the resonator. Therefore, in the embodiment, the resonator includes a plurality of parts having different impedances. According to the embodiment of [E1], the resonator can resonate the electromagnetic waves, even though the size thereof is small, due to the microstrip and the dielectric member.

### [E2]

In the plasma processing apparatus of [E1],
the waveguide portion further includes:
a coaxial waveguide tube having an outer conductor, an annular flange portion, and an inner conductor provided in the outer conductor; and
a lid conductor configured to close an opening between the inner conductor and the outer conductor at one end of the coaxial waveguide tube,
wherein the dielectric member is provided between the one end and the other end of the coaxial waveguide tube, and the resonator further includes a ground conductor provided on the dielectric member, and
wherein the microstrip includes:
a microstrip conductor which is the flange portion;
the dielectric layer having an annular shape and provided on the microstrip conductor; and
an annular ground portion provided on the dielectric layer, the annular ground portion being a part of the ground conductor.

### [E3]

In the plasma processing apparatus of [E2], the dielectric member includes:
a first cylindrical portion interposed between an outer edge of the flange portion and the outer conductor and extending toward the one end of the coaxial waveguide tube;
a second cylindrical portion extending from the flange portion along the inner conductor toward the one end of the coaxial waveguide tube; and
the dielectric layer extending between the first cylindrical portion and the second cylindrical portion.

### [E4]

In the plasma processing apparatus of [E3], the dielectric member provides a recess that is a cavity on the dielectric layer and between the first cylindrical portion and the second cylindrical portion.

### [E5]

In the plasma processing apparatus of [E4], the ground conductor further includes a cylindrical ground portion extending along the first cylindrical portion in the recess.

### [E6]

In the plasma processing apparatus of any one of [E2] to [E5], the plasma processing apparatus further includes an electromagnetic wave supply path having a coaxial structure and connected between a power supply and the coaxial waveguide tube, and the supply path includes a central conductor connected to the flange portion.

### [E7]

In the plasma processing apparatus of any one of [E2] to [E6], the coaxial waveguide tube extends vertically above the chamber, and
the resonator is provided upward from a lower surface of the flange portion.

### [E8]

In the plasma processing apparatus of [E7], the inner conductor of the coaxial waveguide tube constitutes a gas supply tube.

### [E9]

In the plasma processing apparatus of [E8], the plasma processing apparatus further includes:
a substrate support provided within the chamber;
a shower head formed of metal, configured to provide a plurality of gas holes which is open toward a space within the chamber, and provided above the substrate support; and
an introduction portion formed of a dielectric material and provided along an outer periphery of the shower head or along a side wall of the chamber to introduce electromagnetic waves into the chamber therefrom, and
the gas supply tube extends vertically above the chamber, is connected to an upper center of the shower head, and provides a waveguide path connected to the resonator between the resonator and the introduction portion.

### [E10]

In the plasma processing apparatus of [E8] or [E9], the plasma processing apparatus further includes:
a first gas source of a film forming gas connected to the gas supply tube;
a second gas source of a cleaning gas; and
a remote plasma source connected between the second gas source and the gas supply tube.

### [E11]

In the plasma processing apparatus of [E10], the film forming gas includes a silicon-containing gas.

### [E12]

In the plasma processing apparatus of [E10] or [E11], the cleaning gas includes a halogen-containing gas.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A plasma processing apparatus, comprising:
a chamber; and
a waveguide portion configured to propagate electromagnetic waves to generate plasma within the chamber, the waveguide portion including a resonator configured to resonate the electromagnetic waves therein,
wherein the resonator includes a microstrip and a dielectric member, and
wherein a part of the dielectric member constitutes a dielectric layer of the microstrip.

2. The plasma processing apparatus of claim 1, wherein the waveguide portion further comprises:
a coaxial waveguide tube having an outer conductor, an annular flange portion, and an inner conductor provided in the outer conductor; and
a lid conductor configured to close an opening between the inner conductor and the outer conductor at one end of the coaxial waveguide tube,
wherein the dielectric member is provided between the one end and the other end of the coaxial waveguide tube, and the resonator further comprises a ground conductor provided on the dielectric member, and
wherein the microstrip comprises:
a microstrip conductor which is the flange portion;
the dielectric layer having an annular shape and provided on the microstrip conductor; and
an annular ground portion provided on the dielectric layer, the annular ground portion being a part of the ground conductor.

3. The plasma processing apparatus of claim 2, wherein the dielectric member comprises:
a first cylindrical portion interposed between an outer edge of the flange portion and the outer conductor and extending toward the one end of the coaxial waveguide tube;
a second cylindrical portion extending from the flange portion along the inner conductor toward the one end of the coaxial waveguide tube; and
the dielectric layer extending between the first cylindrical portion and the second cylindrical portion.

4. The plasma processing apparatus of claim 3, wherein the dielectric member provides a recess that is a cavity on the dielectric layer and between the first cylindrical portion and the second cylindrical portion.

5. The plasma processing apparatus of claim 4, wherein the ground conductor further comprises a cylindrical ground portion extending along the first cylindrical portion in the recess.

6. The plasma processing apparatus of claim 5, further comprising an electromagnetic wave supply path having a coaxial structure and connected between a power supply and the coaxial waveguide tube,
wherein the supply path includes a central conductor connected to the flange portion.

7. The plasma processing apparatus of claim 2, wherein the coaxial waveguide tube extends vertically above the chamber, and
wherein the resonator is provided from a lower surface of the flange portion to a space above the flange portion.

8. The plasma processing apparatus of claim 7, wherein the inner conductor of the coaxial waveguide tube constitutes a gas supply tube.

9. The plasma processing apparatus of claim 8, further comprising:
a substrate support provided within the chamber;
a shower head formed of metal, configured to provide a plurality of gas holes which is open toward a space within the chamber, and provided above the substrate support; and
an introduction portion formed of a dielectric material and provided along an outer periphery of the shower head or along a side wall of the chamber to introduce electromagnetic waves into the chamber therefrom,
wherein the gas supply tube extends vertically above the chamber, is connected to an upper center of the shower head, and provides a waveguide path connected to the resonator between the resonator and the introduction portion.

10. The plasma processing apparatus of claim 8, further comprising:
a first gas source of a film forming gas connected to the gas supply tube;
a second gas source of a cleaning gas; and
a remote plasma source connected between the second gas source and the gas supply tube.

11. The plasma processing apparatus of claim 10, wherein the film forming gas includes a silicon-containing gas.

12. The plasma processing apparatus of claim 10, wherein the cleaning gas includes a halogen-containing gas.

13. The plasma processing apparatus of claim 2, further comprising an electromagnetic wave supply path having a coaxial structure and connected between a power supply and the coaxial waveguide tube,
wherein the supply path includes a central conductor connected to the flange portion.
